(19) United States
(12) Patent Application Publication
(10) Pub. No.: US 2017/0058394 A1
(43) Pub. Date: Mar. 2, 2017

(54) FILM FORMATION DEVICE AND FILM FORMATION METHOD

(71) Applicant: Shimadzu Corporation, Kyoto (JP)

(72) Inventors: Akina ICHIOKA, Kyoto (JP); Toshinori YOSHIMUTA, Kyoto (JP); Satoshi TOKUDA, Kyoto (JP); Naoki YOSHIOKA, Kyoto (JP); Satoko UENO, Kyoto (JP); Satoru OZAKI, Kyoto (JP)

(21) Appl. No.: 15/210,225

(22) Filed: Jul. 14, 2016

(30) Foreign Application Priority Data
Aug. 26, 2015 (JP) 2015-166423

(51) Int. Cl. C23C 14/20; H01J 37/32; C23C 14/50; C23C 14/34; H01J 37/34

(52) U.S. Cl. CPC C23C 14/205; C23C 14/3407; H01J 37/3426; C23C 14/50; H01J 37/32715

(57) ABSTRACT

A film formation device for forming a metal thin film on a polycarbonate work molded by a resin molding machine, comprises: a film former including a chamber configured to house the work, and a sputtering electrode including a target material and disposed in the chamber; and a carrier configured to carry the work molded by the resin molding machine from the resin molding machine to the chamber within such a short time period that no moisture adheres to a surface of the work.

### BACKGROUND OF THE INVENTION

1. TECHNICAL FIELD

The present invention relates to a device and method for forming a metal thin film on a work molded by a resin molding machine and made of resin such as polycarbonate.

2. BACKGROUND ART

For example, inorganic base materials such as glass have been conventionally used for optical components such as reflectors of headlights and meters in automobiles. However, with the demand for weight reduction for, e.g., improvement in fuel consumption of automobiles, these inorganic base materials have been replaced with resin base materials. Moreover, although plating has been often used as a conventional metal film formation method, such a method has been recently replaced with a dry process such as sputtering in order to reduce an environmental load. For the purpose of providing mirror finish or the texture of metal, a film is formed on an injection-molded resin component by sputtering using metal such as aluminum as a target.

After film formation by sputtering, e.g., a silicon oxide protection film is often formed by plasma CVD to protect against oxidation of the metal film or scratches of the surface of the metal film. That is, the work is, after the film formation by sputtering, carried to another film formation device, and then, plasma CVD using monomer gas such as hexamethyldisiloxane (HMDSO) is performed in a chamber of the film formation device. In this manner, the protection film is formed on the surface of the film formed by sputtering.

The device has been proposed, which is configured such that film formation by sputtering and composite polymerization film formation are performed in the same chamber. Patent Document 1 (JP-A-2011-58048) discloses a film formation device configured such that an electrode for sputtering and an electrode for composite or polymerization film formation are arranged apart from each other by a predetermined distance. In this film formation device, a work and the sputtering electrode are first arranged to face each other. After inert gas is introduced into the chamber, direct current is applied to the sputtering electrode to perform film formation by sputtering. Then, the work is moved such that the work and the composite or polymerization film formation electrode are arranged to face each other. After monomer gas such as HMDSO is introduced into the chamber, high-frequency voltage is applied to the composite or polymerization film formation electrode to perform composite or polymerization film formation. The film formation device of Patent Document 1 is configured such that a shutter is disposed above a target not in use.

Polycarbonate (PC) might be used as a work material on which a film is formed by sputtering as described above. Polycarbonate has characteristics such as favorable adhesion to a metal thin film in sputtering. However, in the case of using polycarbonate as a work material, if moisture is present on a polycarbonate surface in sputtering, hydrolysis occurs due to energy in sputtering, leading to deterioration of the polycarbonate surface. This results in detachment of a metal thin film. In particular, such a phenomenon becomes noticeable when high voltage is applied to a sputtering electrode to perform sputtering for resin under low vacuum.

Even in the case of using resin other than polycarbonate as a work material, when moisture is present on a resin surface in sputtering, a metal thin film is oxidized during sputtering film formation, leading to a lower reflectance of the metal thin film.

The present invention has been made to solve the above-described problems, and is intended to provide a device and method for preventing detachment of a metal thin film in the case of forming the metal thin film on polycarbonate and for improving a metal reflectance in the case of forming a metal thin film on other types of resin.

### SUMMARY OF THE INVENTION

In a first aspect of the invention, a film formation device for forming a metal thin film on a polycarbonate work molded by a resin molding machine, comprises: a film former including a chamber configured to house the work, and a sputtering electrode including a target material and disposed in the chamber; and a carrier configured to carry the work molded by the resin molding machine from the resin molding machine to the chamber within such a short time period that no moisture adheres to a surface of the work.

In a second aspect of the invention, the carrier carries the work from the resin molding machine to the chamber within 60 seconds.

In a third aspect of the invention, a film formation device for forming a metal thin film on a resin work molded by a resin molding machine, comprises: a film former including a chamber configured to house the work, and a sputtering electrode including a target material and disposed in the chamber; and a carrier configured to carry the work molded by the resin molding machine from the resin molding machine to the chamber of the film former. A moisture removal mechanism configured to prevent moisture from adhering to a surface of the work carried by the carrier is disposed at the carrier.

In a fourth aspect of the invention, the moisture removal mechanism is a dried gas supply mechanism configured to supply dried gas into a carrying path of the carrier.

In a fifth aspect of the invention, the moisture removal mechanism is a heating mechanism configured to heat an inside of a carrying path of the carrier.

In a sixth aspect of the invention, the film formation device further comprises: a direct current power source configured to apply direct current voltage to the sputtering electrode such that a power of equal to or higher than 25 watts is applied to every square centimeter of a surface area of the target material.

In a seventh aspect of the invention, a film formation method for forming a metal thin film on a polycarbonate work molded by a resin molding machine, comprises: a molding step of molding the work by the resin molding machine; a carrying step of carrying the work molded by the resin molding machine from the resin molding machine to a chamber within such a short time period that no moisture adheres to a surface of the work; and a film formation step of forming, using a sputtering electrode, the metal thin film on the surface of the work while reducing an inner pressure of the chamber, the sputtering electrode including a target material disposed in the chamber.

In a eighth aspect of the invention, a film formation method for forming a metal thin film on a resin work molded by a resin molding machine, comprises: a molding step of molding the work by the resin molding machine; a carrying step of carrying, via a carrying path to which dried gas is supplied or a heated carrying path, the work molded by the resin molding machine from the resin molding machine to a chamber in a state in which moisture adherence to a surface of the work is prevented; and a film formation step of forming, using a sputtering electrode, the metal thin film on the surface of the work while reducing an inner pressure of the chamber, the sputtering electrode including a target material disposed in the chamber.

According to the first, second and seventh aspects of the invention, the metal thin film can be, using the film former, formed by sputtering without moisture adhering to the surface of the polycarbonate work molded by the resin molding machine. This can prevent hydrolysis on the polycarbonate surface, and as a result, the metal thin film can be solidly formed in close contact with polycarbonate.

According to the third, fourth, fifth, and eighth aspects of the invention, the metal thin film can be, using the film former, formed by sputtering without moisture adhering to the surface of the resin work molded by the resin molding machine. This can improve the reflectance of the metal thin film. In the case of the polycarbonate work, hydrolysis on the polycarbonate surface can be prevented, and as a result, the metal thin film can be solidly formed in close contact with polycarbonate.

According to the sixth aspect of the invention, film formation by sputtering can be performed with high application voltage under low vacuum.

### BRIEF DESCRIPTION OF THE DRAWINGS

FIG. 1 is a schematic diagram of a film formation device of a first embodiment of the present invention;

FIG. 2 is a block diagram of a control system of a film formation device of the present invention;

FIG. 3 is a flowchart of film formation operation;

FIG. 4 is a schematic diagram of a film formation device of a second embodiment of the present invention; and

FIG. 5 is a schematic diagram of a film formation device of a third embodiment of the present invention.

### DETAILED DESCRIPTION OF THE EXEMPLARY EMBODIMENTS

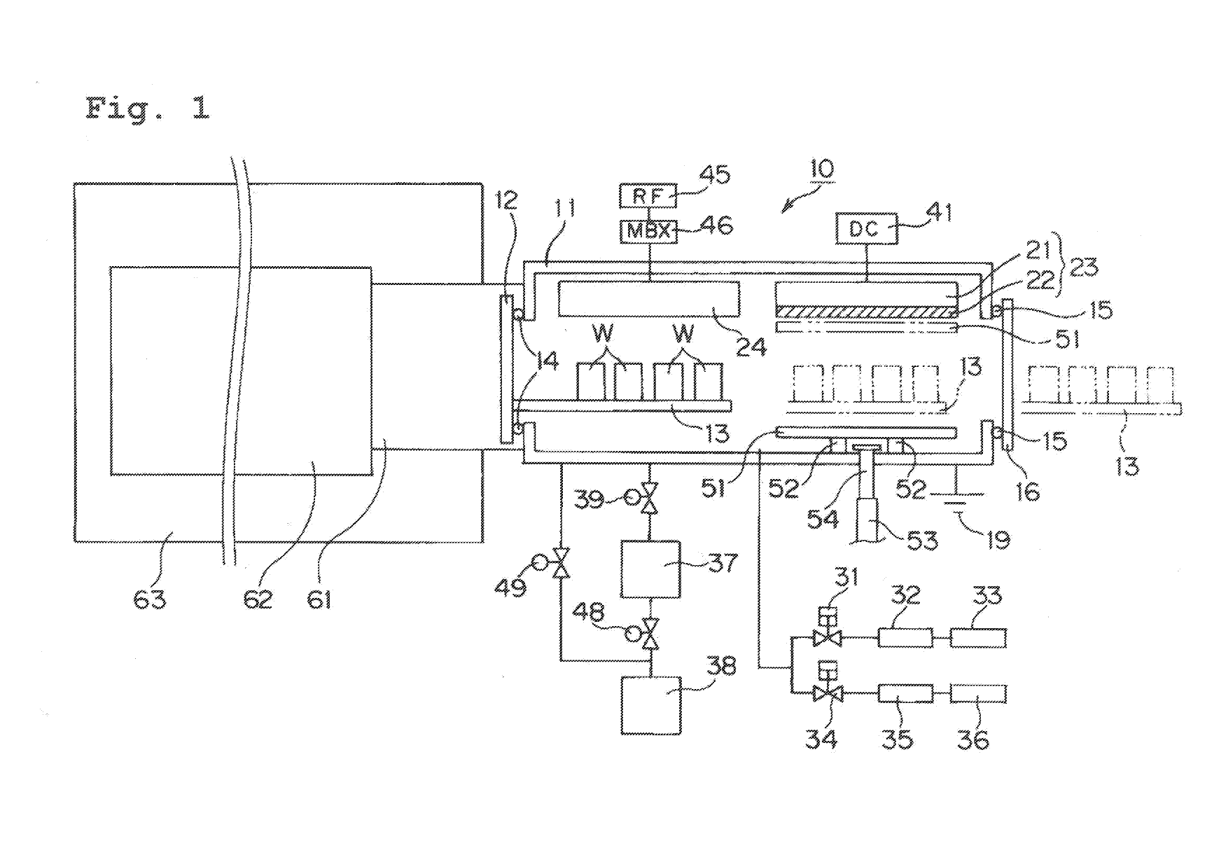

Embodiments of the present invention will be described below with reference to drawings. FIG. 1 is a schematic diagram of a film formation device of a first embodiment of the present invention.

The film formation device of the present embodiment is configured to perform, for a work W made of resin, film formation by sputtering and film formation by plasma CVD. Note that, e.g., polycarbonate is used as the material of the work W. Polycarbonate has characteristics such as inexpensive, a high mechanical strength, a high level of weather resistance, and a high degree of transparency. Moreover, polycarbonate also has characteristics such as a high adhesion to a metal thin film in sputtering. Note that if moisture is present on a polycarbonate surface in sputtering, hydrolysis occurs due to energy in sputtering, leading to deterioration of the polycarbonate surface. This might result in detachment of the metal thin film.

As illustrated in FIG. 1, the film formation device includes a film formation chamber 10 having a main body 11, an inlet openable portion 12, and an outlet openable portion 16. The film formation chamber 10 is connected to a work guide 62 of a resin molding machine 63 via a carrier 61.

The inlet openable portion 12 forming a part of the film formation chamber 10 is movable between a carry-in position at which the injection-molded resin work W is carried into the film formation chamber 10 and a closed position at which the film formation chamber 10 is tightly closed via a packing 14 provided between the main body 11 and the inlet openable portion 12. When the inlet openable portion 12 has moved to the carry-in position, an opening is formed at the left side surface of the film formation chamber 10 so that the work W is carried into the film formation chamber 10 via the opening.

Similarly, the outlet openable portion 16 forming a part of the film formation chamber 10 is movable between a carry-out position at which the resin work W is, after film formation, carried out of the film formation chamber 10 and a closed position at which the film formation chamber 10 is tightly closed via a packing 15 provided between the main body 11 and the outlet openable portion 16. When the outlet openable portion 16 has moved to the carry-out position, an opening is formed at the right side surface of the film formation chamber 10 so that the work W can be carried out of the film formation chamber 10 via the opening.

A work mount 13 configured to carry a plurality of injection-molded works W mounted thereon carries the works W from the work guide 62 of the resin molding machine 63 into the film formation chamber 10 via the carrier 61. Moreover, the work mount 13 carries the works W out of the film formation chamber 10 after film formation. The work mount 13 is, by a cantilever drive mechanism disposed in the work guide 62 of the resin molding machine 63, movable among a work W receiving position in the work guide 62, a film formation position in the film formation chamber 10, and a carry-out position at which the work W is carried out of the film formation chamber 10 in the direction opposite to the work guide 62. Movement of the work mount 13 is driven and controlled by a later-described carrying mechanism driver 91.

The film formation device further includes a sputtering electrode 23 having an electrode portion 21 and a target material 22. The sputtering electrode 23 is, via a not-shown insulating member, attached to the main body 11 of the film formation chamber 10. Note that the main body 11 forming the film formation chamber 10 is connected to the ground 19. The sputtering electrode 23 is connected to a direct current power source 41.

Note that a power source capable of applying direct current voltage to the sputtering electrode 23 such that a power of equal to or higher than 25 watts is applied to every square centimeter of the surface area of the target material 22 is used as the direct current power source 41. That is, the direct current power source 41 applies, as the power to be applied to the sputtering electrode 23, a power of equal to or higher than 25 watts to every square centimeter of the surface area of the target material 22. Aluminum (Al) is used as the target material 22. Note that Al alloy may be used instead of Al.

The film formation device further includes a CVD electrode 24. The CVD electrode 24 is, as in the sputtering electrode 23, attached to the main body 11 of the film formation chamber 10 via a not-shown insulating member. The CVD electrode 24 is also connected to a matching box 46 and a high-frequency power source 45.

The main body 11 forming the film formation chamber 10 is, via an on-off valve 31 and a flow control valve 32, connected to a supply 33 of inert gas such as argon. Moreover, the main body 11 forming the film formation chamber 10 is, via an on-off valve 34 and a flow control valve 35, connected to a supply 36 of raw material gas. HMDSO is used as the raw material gas. Note that as long as the raw material gas is the gas containing Si, hexamethyldisilazane (HMDS) may be used instead of HMDSO, for example. Further, the main body 11 forming the film formation chamber 10 is, via an on-off valve 39, connected to a turbo-molecular pump 37. The turbo-molecular pump 37 is connected to an auxiliary pump 38 via an on-off valve 48. In addition, the auxiliary pump 38 is also connected to the main body 11 forming the film formation chamber 10 via an on-off valve 49.

The film formation device further includes a shutter 51 configured to move, by driving of an air cylinder 53, up and down between a contact position at which the shutter 51 contacts the sputtering electrode 23 to cover the target material 22 as indicated by a virtual line of FIG. 1 and a retracted position at which the shutter 51 is supported by supports 52 in the vicinity of a bottom portion of the film formation chamber 10 as indicated by a solid line of FIG. 1. The shutter 51 is formed of the material functioning as both of a conductor such as metal and a non-magnetic body.

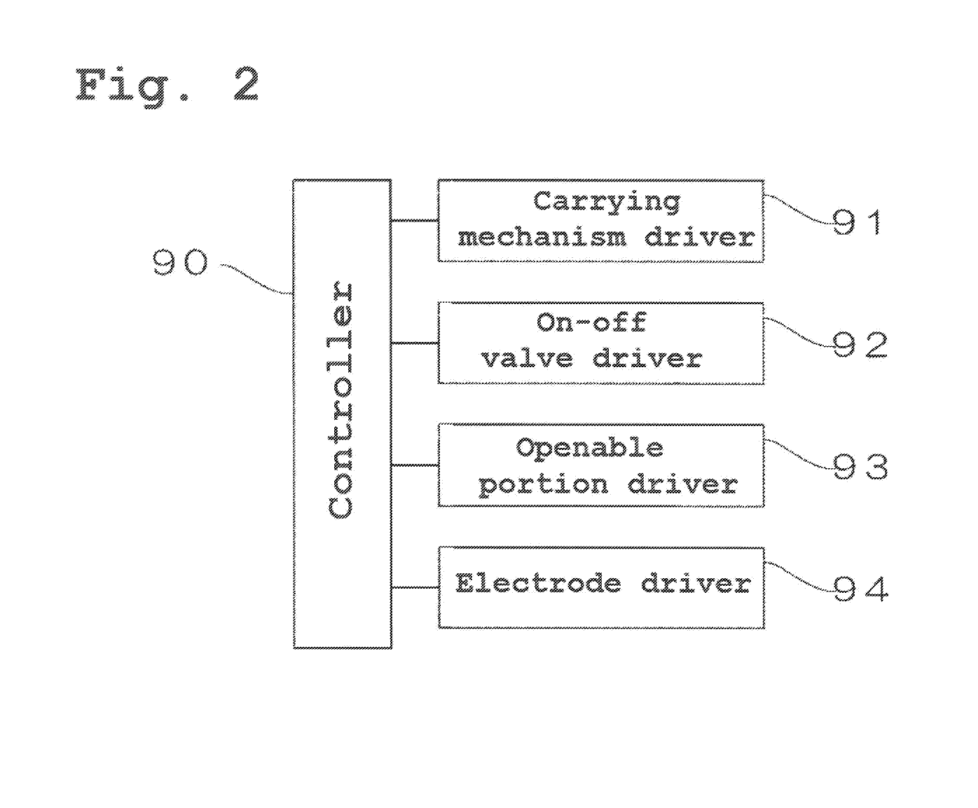

FIG. 2 is a block diagram of a control system of the film formation device of the present invention.

The film formation device includes a controller 90 configured to control the entire device, the controller 90 including, e.g., a CPU configured to execute logical operation, a ROM configured to store an operation program required for device control, and a RAM configured to temporarily store data etc. in control. The controller 90 is also connected to the carrying mechanism driver 91 configured to drive and control a carrying mechanism for moving the work mount 13 illustrated in FIG. 1, an on-off valve driver 92 configured to control opening and closing of, e.g., the on-off valves 31, 34, 39, 48, 49, an openable portion driver 93 configured to control opening and closing of the inlet openable portion 12 and the outlet openable portion 16, and an electrode driver 94 configured to drive and control the sputtering electrode 23 and the CVD electrode 24.

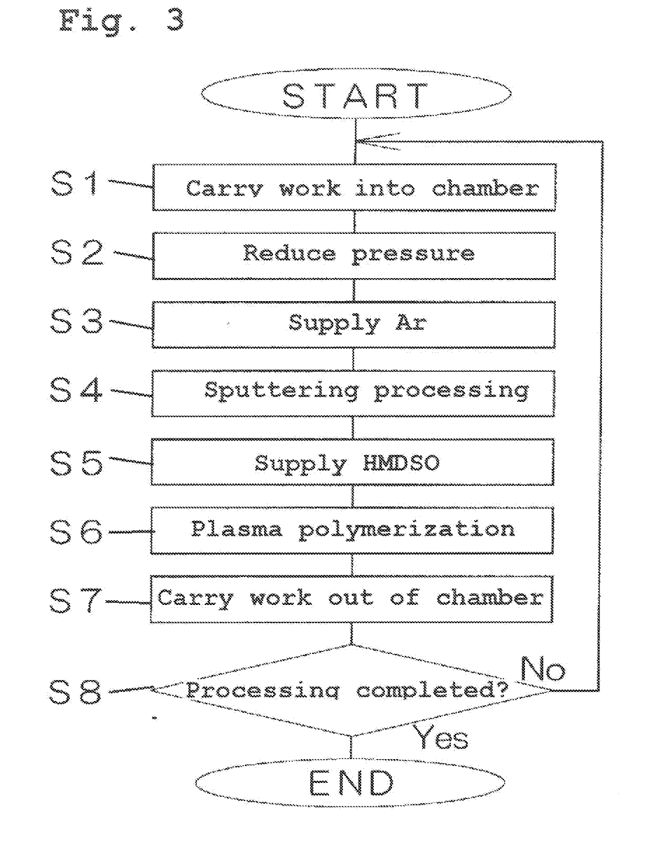

Next, film formation operation by the film formation device having the above-described configuration will be described. FIG. 3 is a flowchart of the film formation operation.

When the film formation operation is performed by the film formation device, the injection-molded work W is carried out of the resin molding machine 63 by the work mount 13, and then, is carried into the film formation chamber 10 by the work mount 13 (step S1). At this point, the inlet openable portion 12 is moved to the carry-in position, and then, the work W mounted on the work mount 13 is moved to face the CVD electrode 24 in the film formation chamber 10 as indicated by the solid line of FIG. 1. Moreover, as indicated by the virtual line of FIG. 1, the shutter 51 is at the contact position at which the shutter 51 contacts the sputtering electrode 23 to cover the target material 22. In this state, a cylinder rod 54 of the air cylinder 53 is in a retracted state in which the cylinder rod 54 is retracted into a main body of the air cylinder 53.

Carrying of the work W from the work guide 62 of the resin molding machine 63 into the film formation chamber 10 is, by the work mount 13, completed within such a short time period that no moisture adheres to the surface of the molded work W carried out of the resin molding machine 63. More specifically, the work mount 13 carries the work W from the work guide 62 of the resin molding machine 63 into the film formation chamber 10 within 60 seconds.

Generally, almost no moisture is adsorbed and adheres to the work W right after resin molding is performed. However, if it takes time to carry the work W from the resin molding machine 63 into the film formation chamber 10, moisture adheres to the surface of the work W. When the film formation by sputtering is performed with moisture adhering to the surface of the polycarbonate work W, embrittlement of the surface of the work W is caused due to hydrolysis on the surface of the work W, leading to detachment of a metal thin film formed by sputtering. Moreover, even in the case of the work W made of other types of resin, when the film formation by sputtering is performed with moisture adhering to the surface of the work W, the reflectance of the metal thin film is lowered due to oxidization of the metal thin film.

For this reason, in the film formation device of the present invention, carrying of the work W from the work guide 62 of the resin molding machine 63 into the film formation chamber 10 is completed within a short time period of 60 seconds such that no moisture adheres to the surface of the molded work W carried out of the resin molding machine 63. This can prevent hydrolysis on the surface of the polycarbonate work W, and as a result, can prevent detachment of the metal thin film formed by sputtering. Moreover, even in the case of the work W made of other types of resin, the film formation by sputtering is performed without moisture adhering to the surface of the work W. Consequently, in the case of using, e.g., aluminum as metal, an aluminum thin film can be formed with a favorable reflectance of about 90%.

After the work W has been carried into the film formation chamber 10, the inlet openable portion 12 is moved to the closed position. Note that, a cutout or the like is formed at the inlet openable portion 12 in order to prevent interference between the inlet openable portion 12 and the work mount 13. Subsequently, the inner pressure of the film formation chamber 10 is reduced to a low vacuum of about 0.1 to 1 pascal (step S2). Before pressure reduction by the turbo-molecular pump 37, the auxiliary pump 38 such as a rotary pump is used to perform pressure reduction to about 100 pascals at high speed. Then, the turbo-molecular pump 37 whose maximum exhaust velocity is equal to or greater than 300 liters per second is used so that the inner pressure of the film formation chamber 10 can be reduced to a low vacuum of about 0.1 to 1 pascal in about 20 seconds.

After the pressure reduction in the film formation chamber 10, the on-off valve 31 opens to supply argon as inert gas from the inert gas supply 33 into the film formation chamber 10, and then, the film formation chamber 10 is filled with the argon such that the degree of vacuum in the film formation chamber 10 reaches 0.5 to 3 pascals (step S3).

Next, the sputtering film formation is performed (step S4). At this point, as indicated by the virtual line of FIG. 1, the work W mounted on the work mount 13 is moved to face the sputtering electrode 23 in the film formation chamber 10. Moreover, as indicated by the solid line of FIG. 1, the shutter 51 is at the retracted position in the vicinity of the bottom portion of the film formation chamber 10. In the case of performing the sputtering film formation, direct current voltage is applied from the direct current power source 41 to the sputtering electrode 23. Thus, a thin film of Al as the target material 22 is formed on the surface of the work W by sputtering.

Note that at this sputtering film formation step, direct current voltage is applied from the direct current power source 41 to the sputtering electrode 23 such that a power of equal to or higher than 25 watts is applied to every square centimeter of the surface area of the target material 22 of the sputtering electrode 23. Thus, even in the case of low vacuum in the film formation chamber 10, the Al thin film is suitably formed on the surface of the resin work W. Note that in the case of performing the sputtering film formation by applying high voltage as described above, even when a polycarbonate work is used for the work W, the film formation by sputtering is performed without moisture adhering to the surface of the work W as described above. This can prevent hydrolysis on the surface of the polycarbonate work W, and can prevent detachment of the metal thin film formed by sputtering.

After the sputtering film formation performed by the above-described steps has been completed, the film formation by plasma CVD using Si oxide is subsequently performed. In the case of performing the plasma CVD film formation, the work W mounted on the work mount 13 is moved to face the CVD electrode 24 in the film formation chamber 10, as indicated by the solid line of FIG. 1. Moreover, as indicated by the virtual line of FIG. 1, the shutter 51 is at the contact position at which the shutter 51 contacts the sputtering electrode 23 to cover the target material 22.

In this state, the on-off valve 34 opens to supply HMDSO as raw material gas from the raw material gas supply 36 into the film formation chamber 10, and as a result, the degree of vacuum in the film formation chamber 10 reaches 0.1 to 10 pascals (step S5). Then, high-frequency voltage is applied from the high-frequency power source 45 to the CVD electrode 24 via the matching box 46, and in this manner, the plasma CVD film formation (plasma polymerization) is performed (step S6). As a result of the plasma CVD using the raw material gas, a protection film 103 is deposited on the surface of the work W (i.e., the surface of the Al thin film).

After the plasma CVD film formation has been completed, the film formation chamber 10 is vented. Subsequently, the work mount 13 is, as indicated by a virtual line of FIG. 1, moved to the outside of the film formation chamber 10 with the outlet openable portion 16 being at the carry-out position. Thus, the work W mounted on the work mount 13 is, after completion of the film formation, carried out of the film formation chamber 10 by the not-shown carrying mechanism (step S7).

Then, it is determined whether or not the processing for all of the works W has been completed (step S8). When the processing for all of the works W has been completed, the device is stopped. On the other hand, when there is an unprocessed work (s) W, the process returns to step 51.

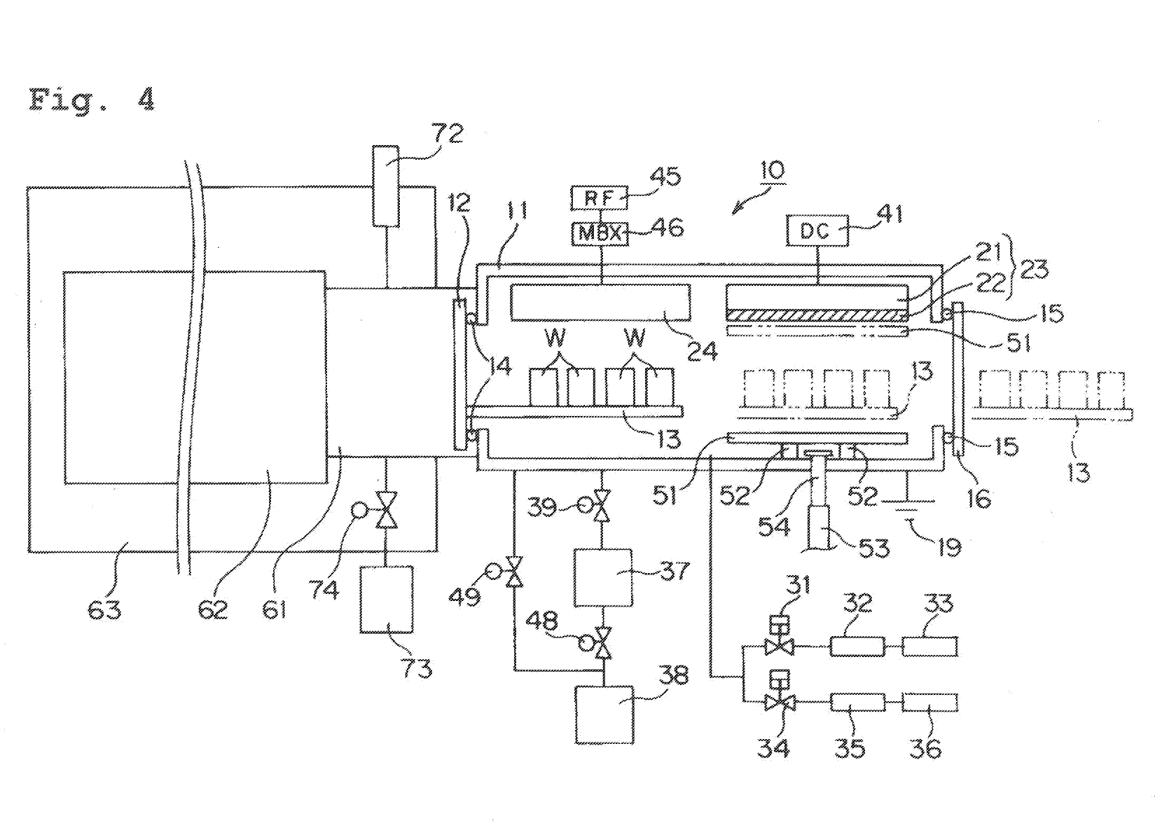

Next, another embodiment of the present invention will be described. FIG. 4 is a schematic diagram of a film formation device of a second embodiment of the present invention. Note that the same reference numerals as those in the first embodiment described above are used to represent corresponding elements in the present embodiment, and description thereof will not be repeated.

In the film formation device of the first embodiment described above, carrying of the work W from the work guide 62 of the resin molding machine 63 into the film formation chamber 10 at the work carry-in step (step S1) is completed within a short time period of 60 seconds such that no moisture adheres to the surface of the molded work W carried out of the resin molding machine 63. This prevents moisture from adhering to the surface of the work W. On the other hand, in the film formation device of the second embodiment, at a carrier 61 configured to carry a work W from a resin molding machine 63 into a film formation chamber 10, a moisture removal mechanism is disposed to prevent moisture from adhering to the surface of the work W carried by the carrier 61. In the film formation device of the second embodiment, a dried gas supply mechanism configured to supply dried gas into a carrying path of the carrier 61 is employed as the moisture removal mechanism.

That is, as illustrated in FIG. 4, the film formation device of the second embodiment is different from the above-described first embodiment in that a dried gas supply 72 and an exhaust pump 73 are additionally provided at the carrier 61. The dried gas supply 72 supplies the carrier 61 with the dried gas containing no moisture, such as dry air or inert gas. Moreover, the exhaust pump 73 opens an on-off valve 74 to exhaust atmosphere from the carrier 61 to the outside.

In the film formation device of the second embodiment, the operation of purging the carrier 61 by the dried gas supplied into the carrier 61 after atmosphere is exhausted from the carrier 61 by the exhaust pump 73 is completed before the work W is carried from a work guide 62 of the resin molding machine 63 into the film formation chamber 10. This can prevent moisture from adhering to the surface of the work W while the molded work W carried out of the resin molding machine 63 is passing through the carrier 61.

Note that the operation after the work carry-in step (step S1) is similar to that of the first embodiment described above.

The film formation device of the second embodiment can prevent hydrolysis on the surface of the polycarbonate work W, and as a result, can prevent detachment of the metal thin film formed by sputtering. Moreover, even in the case of the work W made of other types of resin, the film formation by sputtering is performed without moisture adhering to the surface of the work W. Consequently, in the case of using, e.g., aluminum as metal, an aluminum thin film can be formed with a favorable reflectance of about 90%.

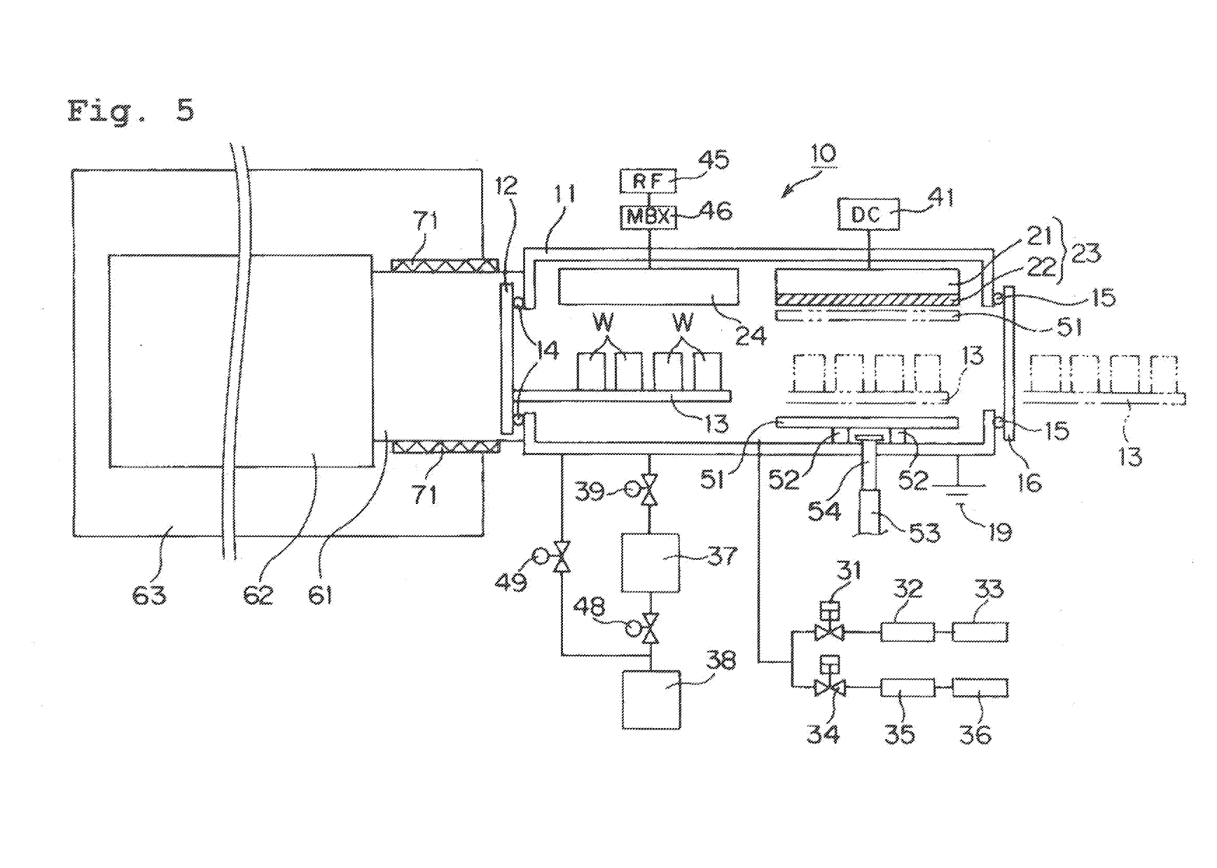

Next, still another embodiment of the present invention will be described. FIG. 5 is a schematic diagram of a film formation device of a third embodiment of the present invention. Note that the same reference numerals as those in the first and second embodiments described above are used to represent corresponding elements in the present embodiment, and description thereof will not be repeated.

In the film formation device of the third embodiment, at a carrier 61 configured to carry a work W from a resin molding machine 63 into a film formation chamber 10, a moisture removal mechanism is disposed to prevent moisture from adhering to the surface of the work W carried by the carrier 61. In the film formation device of the third embodiment, a heating mechanism configured to heat the inside of a carrying path of the carrier 61 is employed as the moisture removal mechanism.

That is, as illustrated in FIG. 5, the film formation device of the third embodiment is different from those of the first and second embodiments described above in that a heater 71 is additionally provided at the carrier 61. The heater 71 has the shape surrounding the carrier 61, and is configured to heat the inside of the carrying path of the carrier 61 from the outer periphery thereof. The function of the heater 71 allows heating of the carrying path to a temperature of about 80 degrees Celsius to about 150 degrees Celsius. Note that such a heating temperature is preferably the temperature lower than a glass-transition temperature of the resin forming the work W by about several tens of degrees.

In the film formation device of the third embodiment, the operation of heating the inside of the carrier 61 to a predetermined temperature by the function of the heater 71 is completed before the work W is carried from a work guide 62 of the resin molding machine 63 into the film formation chamber 10. This can prevent moisture from adhering to the surface of the work W while the molded work W carried out of the resin molding machine 63 is passing through the carrier 61.

Note that the operation after the work carry-in step (step S1) is similar to those of the first and second embodiments described above.

The film formation device of the third embodiment can prevent hydrolysis on the surface of the polycarbonate work W, and as a result, can prevent detachment of a metal thin film formed by sputtering. Moreover, even in the case of the work W made of other types of resin, the film formation by sputtering is performed without moisture adhering to the surface of the work W. Consequently, in the case of using, e.g., aluminum as metal, an aluminum thin film can be formed with a favorable reflectance of about 90%.

Note that in any of the above-described embodiments, the case of applying the present invention to the film formation device configured to continuously perform the film formation by sputtering and the film formation by plasma CVD in the same film formation chamber 10 has been described, but the present invention may be applied to a film formation device configured to perform only the film formation by sputtering.

What is claimed is:

1. A film formation device for forming a metal thin film on a polycarbonate work molded by a resin molding machine, comprising:
a film former including
a chamber configured to house the work, and
a sputtering electrode including a target material and disposed in the chamber; and
a carrier configured to carry the work molded by the resin molding machine from the resin molding machine to the chamber within such a short time period that no moisture adheres to a surface of the work.

2. The film formation device according to claim 1, wherein
the carrier carries the work from the resin molding machine to the chamber within 60 seconds.

3. A film formation device for forming a metal thin film on a resin work molded by a resin molding machine, comprising:
a film former including
a chamber configured to house the work, and
a sputtering electrode including a target material and disposed in the chamber; and
a carrier configured to carry the work molded by the resin molding machine from the resin molding machine to the chamber of the film former,
wherein a moisture removal mechanism configured to prevent moisture from adhering to a surface of the work carried by the carrier is disposed at the carrier.

4. The film formation device according to claim 3, wherein
the moisture removal mechanism is a dried gas supply mechanism configured to supply dried gas into a carrying path of the carrier.

5. The film formation device according to claim 3, wherein
the moisture removal mechanism is a heating mechanism configured to heat an inside of a carrying path of the carrier.

6. The film formation device according to claim 1, further comprising:
a direct current power source configured to apply direct current voltage to the sputtering electrode such that a power of equal to or higher than 25 watts is applied to every square centimeter of a surface area of the target material.

7. A film formation method for forming a metal thin film on a polycarbonate work molded by a resin molding machine, comprising:
a molding step of molding the work by the resin molding machine;
a carrying step of carrying the work molded by the resin molding machine from the resin molding machine to a chamber within such a short time period that no moisture adheres to a surface of the work; and
a film formation step of forming, using a sputtering electrode, the metal thin film on the surface of the work while reducing an inner pressure of the chamber, the sputtering electrode including a target material disposed in the chamber.

8. A film formation method for forming a metal thin film on a resin work molded by a resin molding machine, comprising:
a molding step of molding the work by the resin molding machine;
a carrying step of carrying, via a carrying path to which dried gas is supplied or a heated carrying path, the work molded by the resin molding machine from the resin molding machine to a chamber in a state in which moisture adherence to a surface of the work is prevented; and
a film formation step of forming, using a sputtering electrode, the metal thin film on the surface of the work while reducing an inner pressure of the chamber, the sputtering electrode including a target material disposed in the chamber.
